(19) United States
(12) Patent Application Publication
(10) Pub. No.: US 2026/0304738 A1
(43) Pub. Date: Oct. 1, 2026

(54) SEMICONDUCTOR DEVICES

(71) Applicant: Samsung Electronics Co., Ltd., Suwon-si (KR)

(72) Inventors: Eunsuk Jang, Suwon-si (KR); Woochul Kim, Suwon-si (KR); Hyebin Kim, Suwon-si (KR); Gyuhwan Oh, Suwon-si (KR); Jihoon Choi, Suwon-si (KR)

(73) Assignee: Samsung Electronics Co., Ltd., Suwon-si (KR)

(21) Appl. No.: 19/420,633

(22) Filed: Dec. 15, 2025

(30) Foreign Application Priority Data
Apr. 1, 2025 (KR) 10-2025-0042364

(51) Int. Cl. H10B 12/00

(52) U.S. Cl. CPC H10B 12/30; H10B 12/03; H10B 12/05

(57) ABSTRACT

A semiconductor device includes a substrate, a plurality of semiconductor patterns extending in a first horizontal direction, above the substrate, and spaced apart from one another in a second horizontal direction and a vertical direction, which intersect the first horizontal direction, the plurality of semiconductor patterns each including a first end and a second end, a bit line connected to the first ends of the plurality of semiconductor patterns and extending in the vertical direction, a plurality of word lines extending in the second horizontal direction, above the plurality of semiconductor patterns, and a lower separation structure partially passing through the substrate in the vertical direction and located between the substrate and the bit line, the lower separation structure extending above the substrate to cover at least one semiconductor pattern.

### CROSS-REFERENCE TO RELATED APPLICATIONS

This present application claims priority to and the benefit under 35 U.S.C. § 119(a)-(d) of Korean Patent Application No. 10-2025-0042364, filed on Apr. 1, 2025, in the Korean Intellectual Property Office, the entire disclosure of which is incorporated herein by reference.

### FIELD

The disclosed concepts relate to a semiconductor device, and more particularly, to a three-dimensional semiconductor device.

### BACKGROUND

The demand for smaller, more multifunctional, and higher-performance electronic products has led to the need for high-capacity semiconductor devices, and in order to provide high-capacity semiconductor devices, an increased degree of integration is required. Three-dimensional semiconductor devices are therefore being proposed in which a plurality of memory cells are stacked on substrates in the vertical direction to increase memory capacity.

### SUMMARY

The disclosed concepts provide a three-dimensional semiconductor device having improved electrical characteristics.

According to aspects of the disclosed concepts, there is provided a semiconductor device including a substrate, a plurality of semiconductor patterns extending in a first horizontal direction, above the substrate, and spaced apart from one another in a second horizontal direction and a vertical direction, which intersect the first horizontal direction, the plurality of semiconductor patterns each including a first end and a second end, a bit line connected to the first ends of the plurality of semiconductor patterns and extending in the vertical direction, a plurality of word lines extending in the second horizontal direction, above the plurality of semiconductor patterns, and a lower separation structure partially passing through the substrate in the vertical direction and located between the substrate and the bit line, the lower separation structure extending above the substrate to cover at least one semiconductor pattern.

According to aspects of the disclosed concepts, there is provided a semiconductor device including a substrate, a plurality of semiconductor patterns extending in a first horizontal direction, above the substrate, and spaced apart from one another in a second horizontal direction and a vertical direction, which intersect the first horizontal direction, the plurality of semiconductor patterns each including a first end and a second end, a bit line connected to the first ends of the plurality of semiconductor patterns and extending in the vertical direction, a plurality of word lines extending in the second horizontal direction, above the plurality of semiconductor patterns, a plurality of cell capacitors respectively connected to the second ends of the plurality of semiconductor patterns, a plate electrode connected to the plurality of cell capacitors and extending in the vertical direction, and a first lower separation structure partially passing through the substrate in the vertical direction and located between the substrate and the plate electrode, the first lower separation structure extending above the substrate to cover at least one semiconductor pattern.

According to aspects of the disclosed concepts, there is provided a semiconductor device including a substrate, a plurality of semiconductor patterns extending in a first horizontal direction, above the substrate, and spaced apart from one another in a second horizontal direction and a vertical direction, which intersect the first horizontal direction, the plurality of semiconductor patterns each including a first end and a second end, a bit line connected to the first ends of the plurality of semiconductor patterns and extending in the vertical direction, a plurality of word lines respectively surrounding the plurality of semiconductor patterns and extending in the second horizontal direction, a plurality of cell capacitors respectively connected to the second ends of the plurality of semiconductor patterns, a plate electrode connected to the plurality of cell capacitors and extending in the vertical direction, and a lower separation structure partially passing through the substrate in the vertical direction and located at one or more positions among a position between the substrate and the bit line and a position between the substrate and the plate electrode, wherein the lower separation structure includes a first vertical section extending in the vertical direction, above the substrate, to cover at least one semiconductor pattern, and a second vertical section extending in the vertical direction and partially passing through the substrate, and wherein a thickness of the second vertical section of the lower separation structure is less than a thickness of the first vertical section of the lower separation structure.

According to aspects of the disclosed concepts, there is provided a method of manufacturing a semiconductor device, the method including forming a mold stack including a sacrificial mold layer and a semiconductor layer which are alternately stacked in a vertical direction on a substrate, partially removing the mold stack and patterning the semiconductor layer to form semiconductor patterns that extend in a first horizontal direction, forming, above the semiconductor patterns, a plurality of word lines that extend in a second horizontal direction intersecting the first horizontal direction, forming a first insulating layer and a gap-fill insulating layer that cover the plurality of word lines, forming a hole passing through the gap-fill insulating layer and part of the substrate in the vertical direction, and forming, inside the hole, a first lower separation structure partially passing through the substrate in the vertical direction, and forming, on the first lower separation structure, a bit line that extends in the vertical direction and is connected to one end of each of the semiconductor patterns, wherein the first lower separation structure includes a first vertical section extending in the vertical direction, above the substrate, to cover at least one semiconductor pattern, and a second vertical section extending in the vertical direction and partially passing through the substrate.

In some embodiments, the forming of the first lower separation structure may include enlarging the hole by removing the gap-fill insulating layer and part of the first insulating layer, forming a second insulating layer and a conductive layer, on the first insulating layer and the substrate, forming, on the conductive layer, a gap-fill dielectric layer that partially fills the hole, removing the conductive layer such that the conductive layer has the same vertical level as the gap-fill dielectric layer, removing the gap-fill dielectric layer, and removing the first insulating layer and the second insulating layer such that the first insulating layer and the second insulating layer have the same vertical level as an upper surface of the conductive layer.

In some embodiments, in the forming of the gap-fill dielectric layer, the gap-fill dielectric layer may be formed such that a vertical level of the upper surface of the gap-fill dielectric layer is higher than or equal to a vertical level of an upper surface of a semiconductor pattern located lowermost.

In some embodiments, the hole may be provided in plurality spaced apart from one another in a horizontal direction, and in the forming of the gap-fill dielectric layer, a plurality of gap-fill dielectric layers may respectively fill the plurality of holes, and upper surfaces of the plurality of gap-fill dielectric layers may have the same vertical level.

In some embodiments, the gap-fill dielectric layer may include carbon (C).

In some embodiments, the gap-fill dielectric layer may include flowable oxide, and the forming of the gap-fill dielectric layer may be performed by a flowable chemical vapor deposition (F-CVD) process.

In some embodiments, the forming of the first lower separation structure may further include forming an oxide film layer on the first insulating layer in the first vertical section before forming the second insulating layer on the first insulating layer.

In some embodiments, the first vertical section of the first lower separation structure may have a first thickness, and the second vertical section of the first lower separation structure may have a second thickness that is less than the first thickness.

In some embodiments, the first vertical section and the second vertical section of the first lower separation structure may not overlap one another in the vertical direction.

In some embodiments, the method may further include forming a second lower separation structure, which is spaced apart from the first lower separation structure in a horizontal direction and partially passes through the substrate, and forming, above the second lower separation structure, a plurality of cell capacitors that are respectively connected to the other ends of the semiconductor patterns.

### BRIEF DESCRIPTION OF THE DRAWINGS

Embodiments will be more clearly understood from the following detailed description taken in conjunction with the accompanying drawings in which:

FIG. 1 is a block diagram schematically showing a semiconductor device according to embodiments;

FIG. 2 is a circuit diagram showing a cell array region of FIG. 1;

FIG. 3 is a schematic perspective view showing a memory cell region of FIG. 1;

FIG. 4 is a cross-sectional view of a memory cell region taken along line A1-A1′ of FIG. 3;

FIG. 5 is an enlarged cross-sectional view of region EX1 of FIG. 4;

FIG. 6 is a cross-sectional view of a semiconductor device according to embodiments, in a region corresponding to the cross-section taken along line A1-A1′ of FIG. 3;

FIG. 7 is an enlarged cross-sectional view of region EX2 of FIG. 6;

FIG. 8 is a cross-sectional view of a semiconductor device according to embodiments, in a region corresponding to the cross-section taken along line A1-A1′ of FIG. 3;

FIG. 9 is an enlarged cross-sectional view of region EX3 of FIG. 8;

FIG. 10 is a cross-sectional view of a semiconductor device according to embodiments, in a region corresponding to the cross-section taken along line A1-A1′ of FIG. 3; and

FIGS. 11 to 27 are cross-sectional views showing a method of manufacturing a semiconductor device, according to embodiments.

### DETAILED DESCRIPTION

Hereinafter, embodiments are described in detail with reference to the accompanying drawings.

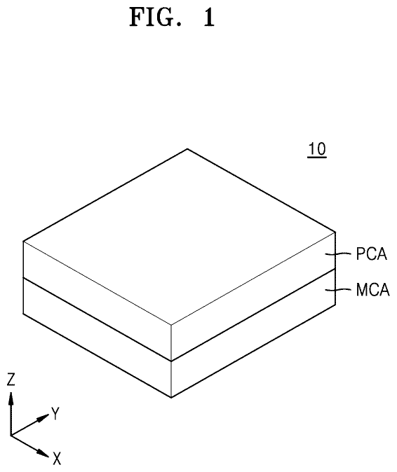

FIG. 1 is a block diagram schematically showing a semiconductor device according to embodiments.

Referring to FIG. 1, a semiconductor device 10 may include a cell array region MCA and a peripheral circuit region PCA at a higher vertical level than the cell array region MCA.

In embodiments, the cell array region MCA may include a memory cell region of a dynamic random-access memory (DRAM) device, and the peripheral circuit region PCA may include a core region or a peripheral circuit region of the DRAM device. For example, the peripheral circuit region PCA may include a peripheral circuit transistor for transmitting a signal and/or power to a memory cell array of the cell array region MCA. In embodiments, the peripheral circuit transistor may constitute various circuits, such as a command decoder, control logic, an address buffer, a row decoder, a column decoder, a sense amplifier, and a data input/output circuit.

FIG. 1 illustrates an example in which the peripheral circuit region PCA is at a higher vertical level than the cell array region MCA (e.g., an example in which the peripheral circuit region PCA is disposed on the cell array region MCA). However, in some embodiments, the semiconductor device 100 may be arranged upside down so that the cell array region MCA is at a higher vertical level than the peripheral circuit region PCA.

In embodiments, the peripheral circuit region PCA and the cell array region MCA are individually formed on separate wafers, and then, the peripheral circuit region PCA and the cell array region MCA may be attached to one another by using bonding pads. In some embodiments, the peripheral circuit region PCA may be formed first on a peripheral circuit wafer, and then, the cell array region MCA may be formed on the peripheral circuit region PCA.

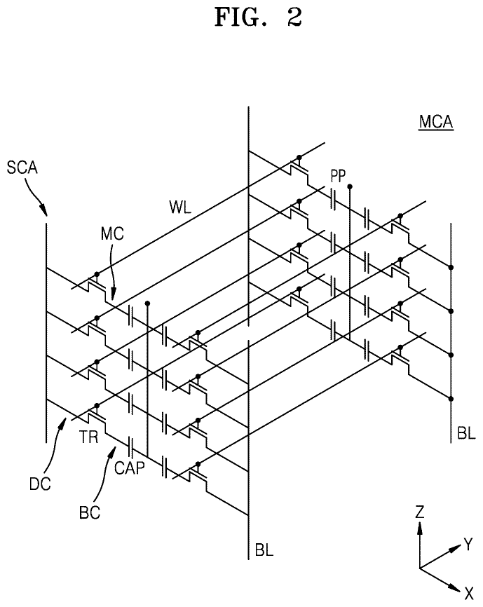

FIG. 2 is a circuit diagram showing the cell array region MCA of FIG. 1.

Referring to FIG. 2, the cell array region MCA may include a plurality of sub cell arrays SCA. The plurality of sub cell arrays SCA may be spaced apart from one another in a second horizontal direction Y.

The sub cell arrays SCA may include a plurality of bit lines BL, a plurality of word lines WL, and a plurality of memory cells MC. Each of the plurality of memory cells MC may include one cell transistor TR and one cell capacitor CAP connected to the cell transistor TR. Each of the plurality of memory cells MC may have a 1 transistor-1 capacitor structure.

The plurality of word lines WL may each extend in the second horizontal direction Y and may be spaced apart from one another in a first horizontal direction X and a vertical direction Z. The plurality of bit lines BL may each extend in the vertical direction Z and may be spaced apart from one another in the first horizontal direction X and the second horizontal direction Y. One cell transistor TR may be located between one word line WL and one bit line BL.

A gate of the cell transistor TR may be connected to the word line WL, and a source of the cell transistor TR may be connected to the bit line BL via a first contact DC. The cell transistor TR may be connected to the cell capacitor CAP via a second contact BC. A drain of the cell transistor TR may be connected to a first electrode of the cell capacitor CAP via the second contact BC, and a second electrode of the cell capacitor CAP may be connected to a plate electrode PP.

In one sub cell array SCA, a plurality of cell transistors TR may be arranged at positions that overlap one another in the vertical direction Z. In one sub cell array SCA, a plurality of cell capacitors CAP may be arranged at positions that overlap one another in the vertical direction Z. One cell transistor TR and one cell capacitor CAP may be arranged side by side at the same vertical level, and the plurality of memory cells MC each including one cell transistor TR and one cell capacitor CAP may be stacked in the vertical direction Z. The storage capacity of the sub cell array SCA may vary depending on the number of memory cells MC or the number of layers thereof (e.g., the number of cell capacitors CAP or the number of layers thereof) stacked in the vertical direction Z.

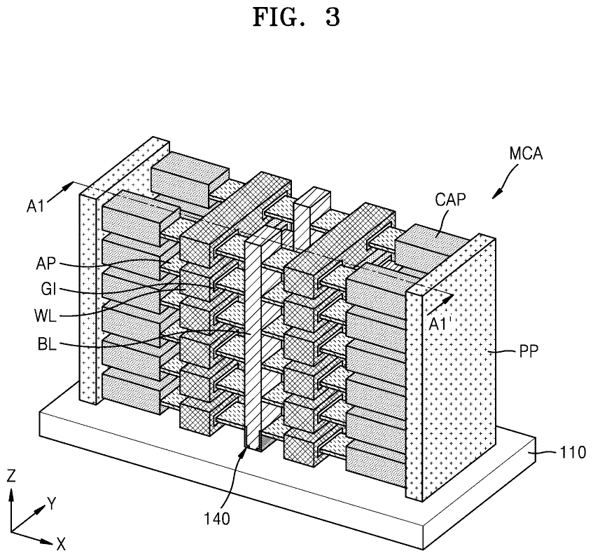

FIG. 3 is a schematic perspective view showing the memory cell region of FIG. 1.

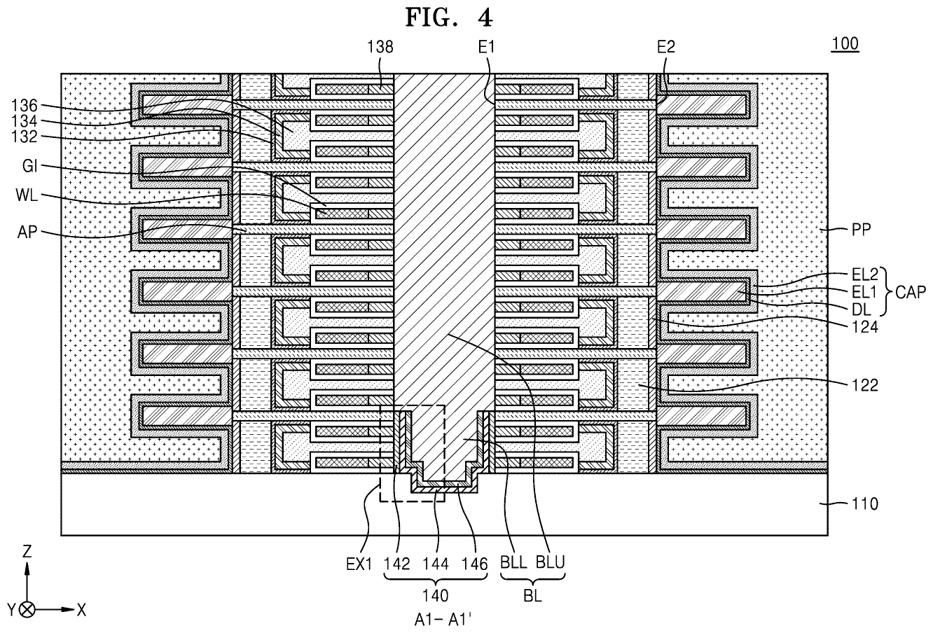

FIG. 4 is a cross-sectional view of the memory cell region taken along line A1-A1′ of FIG. 3.

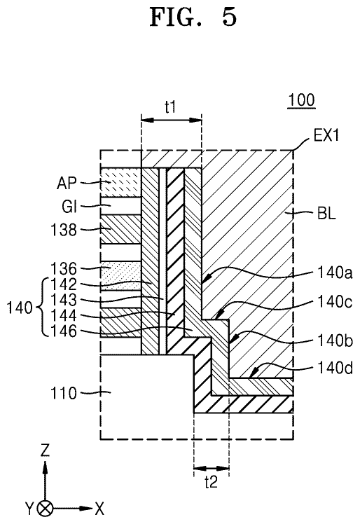

FIG. 5 is an enlarged cross-sectional view of region EX1 of FIG. 4.

Referring to FIGS. 3 to 5, in the cell array region MCA, a plurality of semiconductor patterns AP may extend in the first horizontal direction X above a substrate 110 and be spaced apart from one another in the second horizontal direction Y and the vertical direction Z.

In embodiments, the substrate 110 may include Si, Ge, or SiGe. In embodiments, the substrate 110 may include a silicon-on-insulator (SOI) substrate or a germanium-on-insulator (GeOI) substrate.

In embodiments, the plurality of semiconductor patterns AP may include, for example, undoped semiconductor materials or doped semiconductor materials. In some embodiments, the plurality of semiconductor patterns AP may include polysilicon. In some embodiments, the plurality of semiconductor patterns AP may include amorphous metal oxide, polycrystalline metal oxide, or a combination of the amorphous metal oxide and the polycrystalline metal oxide, and may include, for example, at least one of In—Ga-based oxide (IGO), In—Zn-based oxide (IZO), and In—Ga—Zn-based oxide (IGZO). In some embodiments, the plurality of semiconductor patterns AP may include two-dimensional (2D) material semiconductors. For example, the 2D material semiconductors may include MoS₂, WSe₂, graphene, carbon nano tubes, or a combination thereof.

The plurality of word lines WL may be spaced apart from one another in the vertical direction Z, and may each be disposed on the upper surfaces, the bottom surfaces, and the sidewalls of the plurality of semiconductor patterns AP and extend in the second horizontal direction Y. One word line WL among the plurality of word lines WL may extend in the second horizontal direction Y while surrounding the plurality of semiconductor patterns AP spaced apart from one another in the second horizontal direction Y. Two word lines WL that are spaced apart from one another in the vertical direction Z among the plurality of word lines WL may be arranged at positions overlapping one another in the vertical direction Z. As the plurality of word lines WL are arranged so as to surround the upper surface, the bottom surface, and the sidewall of the semiconductor pattern AP, the semiconductor device 100 may be referred to as a gate-all-around type device.

In embodiments, a gate insulating layer GI may be located between the word line WL and the semiconductor pattern AP. The gate insulating layer GI may include at least one selected from a group consisting of a ferroelectric material and a high-k dielectric material having a higher dielectric constant than silicon oxide. In embodiments, the gate insulating layer GI includes at least one material selected from a group consisting of hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (SrTaBiO), bismuth iron oxide (BiFeO), strontium titanium oxide (SrTiO), yttrium oxide (YO), aluminum oxide (AlO), and lead scandium tantalum oxide (PbScTaO).

In embodiments, each of the semiconductor patterns AP may include a first end E1 adjacent to a bit line BL and a second end E2 opposite to the first end E1 and adjacent to the cell capacitor CAP. The second end E2 of each of the semiconductor patterns AP may be surrounded by a first gap-fill insulating layer 122 and a first insulating liner 124. The first gap-fill insulating layer 122 may be located between second ends E2 of two semiconductor patterns AP adjacent to one another in the vertical direction Z, and the first insulating liner 124 may extend in the vertical direction Z on a first sidewall of the first gap-fill insulating layer 122. A second insulating liner 132 and a third insulating liner 134 may extend from a second sidewall of the first gap-fill insulating layer 122 onto the upper surface and the bottom surface of the semiconductor pattern AP. A portion of a second gap-fill insulating layer 136 may be at a position vertically overlapping both the second insulating liner 132 and the third insulating liner 134, and another portion of the second gap-fill insulating layer 136 may be located between the plurality of word lines WL. A spacer 138 may be disposed on a sidewall of the word line WL adjacent to the first end E1 of the semiconductor pattern AP, and the gate insulating layer GI may be disposed on the upper surface and the bottom surface of the spacer 138.

In embodiments, the first gap-fill insulating layer 122, the second gap-fill insulating layer 136, the first insulating liner 124, the second insulating liner 132, the third insulating liner 134, and the spacer 138 may each be formed by using at least one of silicon oxide, silicon nitride, and silicon oxynitride.

In embodiments, the gate insulating layer GI may be located between the word line WL and the semiconductor pattern AP, and the gate insulating layer GI may be located between the word line WL and the second gap-fill insulating layer 136. For example, the second gap-fill insulating layer 136 may be located between two semiconductor patterns AP adjacent to one another in the vertical direction Z and spaced apart from the two semiconductor patterns AP. The word line WL located between the upper surface of the second gap-fill insulating layer 136 and a first semiconductor pattern that is at a higher level among the two semiconductor patterns AP may be referred to as a first word line. The word line WL located between the bottom surface of the second gap-fill insulating layer 136 and a second semiconductor pattern that is at a lower level among the two semiconductor patterns AP may be referred to as a second word line. The gate insulating layer GI may be located on the upper surface and the bottom surface of the first word line and on the upper surface and the bottom surface of the second word line.

The first ends E1 of the plurality of semiconductor patterns AP may be connected to the plurality of bit lines BL. Also, the plurality of bit lines BL may each extend in the vertical direction Z on the substrate 110 and may be spaced apart from one another in the second horizontal direction Y. The plurality of bit lines BL may include any one of a doped semiconductor material, conductive metal nitride, metal, and a metal-semiconductor compound. An insulating layer extending in the vertical direction Z may be located between two bit lines BL adjacent to one another in the second horizontal direction Y. The spacer 138 may be located between the sidewall of the bit line BL and the word line WL, and thus, the word line WL may be electrically insulated from the bit line BL.

In embodiments, one bit line BL may be located between one semiconductor pattern AP and another semiconductor pattern AP spaced apart therefrom in the first horizontal direction X, and two transistors formed by these two semiconductor patterns AP may share one bit line BL. An ohmic metal layer including metal silicide may be further formed between the bit line BL and the first end E1 of the semiconductor pattern AP.

In embodiments, the cell capacitor CAP may include a first electrode EL1, a capacitor dielectric layer DL, and a second electrode EL2.

In embodiments, the first electrode EL1 may be connected to the second end E2 of the semiconductor pattern AP, and the first electrode EL1 may have a bar shape or a pillar shape extending in the first horizontal direction X.

In embodiments, the capacitor dielectric layer DL may be disposed on the first electrode EL1 and, for example, may be conformally disposed on the upper surface, the bottom surface, and the sidewall of the first electrode EL1.

In embodiments, the second electrode EL2 may be disposed on the capacitor dielectric layer DL and may be conformally disposed on the upper surface, the bottom surface, and the sidewall of the capacitor dielectric layer DL. For example, the capacitor dielectric layer DL may be located between the first electrode EL1 and the second electrode EL2.

In embodiments, the first electrode EL1 and the second electrode EL2 may include doped semiconductor materials, conductive metal nitride, such as titanium nitride, tantalum nitride, niobium nitride, and tungsten nitride, metal, such as ruthenium, iridium, titanium, and tantalum, and conductive metal oxide, such as iridium oxide and niobium oxide. In embodiments, the capacitor dielectric layer DL may include at least one selected from a group consisting of a ferroelectric material and a high-k dielectric material having a higher dielectric constant than silicon oxide. In some embodiments, the capacitor dielectric layer DL includes at least one material selected from a group consisting of hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (SrTaBiO), bismuth iron oxide (BiFeO), strontium titanium oxide (SrTiO), yttrium oxide (YO), aluminum oxide (AlO), and lead scandium tantalum oxide (PbScTaO).

The plate electrode PP may extend in the vertical direction Z and the second horizontal direction Y, on one side of the cell capacitor CAP. The second electrode EL2 of the cell capacitor CAP may be electrically connected to the plate electrode PP.

In embodiments, the semiconductor device 100 according to the inventive concept may include a lower separation structure 140. The lower separation structure 140 may partially pass through the substrate 110 in the vertical direction Z and be located between the substrate 110 and the bit line BL. The lower separation structure 140 may have a shape surrounding the lower end of the bit line BL and may extend in the second horizontal direction Y.

The bit line BL may include a lower region BLL and an upper region BLU. The lower region BLL may include a region in contact with the lower separation structure 140, and the upper region BLU may include a region that extends in the vertical direction Z on the lower region BLL and is in contact with the first ends E1 of the plurality of semiconductor patterns AP.

In embodiments, the width of the lower region BLL in the first horizontal direction X may be less than the width of the upper region BLU in the first horizontal direction X. In this case, the lower region BLL may have a shape of which the width in the first horizontal direction X decreases toward the substrate 110. For example, the lower region BLL may include a first lower region passing through the substrate 110 and a second lower region disposed on the first lower region. The width of the first lower region in the first horizontal direction X may be less than the width of the second lower region in the first horizontal direction X. Here, the first lower region may represent a region that is in contact with the sidewall of a first vertical section 140a of the lower separation structure 140, and the second lower region may represent a region that is in contact with the sidewall of a second vertical section 140b of the lower separation structure 140.

The lower region BLL may cover the lower separation structure 140, and the bottom surface of the lower region BLL may have the same profile as the upper surface of the lower separation structure 140. For example, the bottom surface of the lower region BLL may cover the sidewalls and the upper surface of the lower separation structure 140.

In embodiments, the lower separation structure 140 may include the first vertical section 140a extending in the vertical direction Z above the substrate 110 and the second vertical section 140b extending in the vertical direction Z and partially passing through the substrate 110.

The first vertical section 140a may be located between the semiconductor pattern AP and the bit line BL and extend in the vertical direction Z. The first vertical section 140a may extend in the vertical direction Z above the substrate 110 so as to cover at least one of the semiconductor patterns AP. Also, the lower separation structure 140 may include a pair of first vertical sections 140a, and the upper surfaces of the pair of first vertical sections 140a may have the same vertical level.

Specifically, the first vertical section 140a may partially cover the semiconductor pattern AP, the gate insulating layer GI, the spacer 138, and the second gap-fill insulating layer 136. FIG. 4 shows that the first vertical section 140a covers only the semiconductor pattern AP located lowermost among the plurality of semiconductor patterns AP, but the inventive concept is not limited thereto.

The second vertical section 140b may be located between the substrate 110 and the bit line BL and extend in the vertical direction Z. Also, the lower separation structure 140 may include a pair of second vertical sections 140b, and the upper surfaces of the pair of second vertical sections 140b may have the same vertical level.

The lower separation structure 140 may include a first horizontal section 140c and a second horizontal section 140d. The first horizontal section 140c may be located between the first vertical section 140a and the second vertical section 140b and extend in the first horizontal direction X. The first horizontal section 140c may connect the first vertical section 140a to the second vertical section 140b. Accordingly, the first vertical section 140a may not overlap the second vertical section 140b in the vertical direction Z. That is, the lower separation structure 140 may have a shape including a stepped region. For example, the lower separation structure 140 may include a stepped region in the vicinity of the interface between the substrate 110 and the bit line BL.

The second horizontal section 140d may be connected to one end of the second vertical section 140b and extend in the first horizontal direction X. The second horizontal section 140d may connect the pair of second vertical sections 140b that are spaced apart from one another in the first horizontal direction X. The second horizontal section 140d may cover the bottom surface of the bit line BL.

In embodiments, the lower separation structure 140 may include a first insulating layer 142, a second insulating layer 144, and a conductive layer 146. The first insulating layer 142, the second insulating layer 144, and the conductive layer 146 may be sequentially disposed on the semiconductor pattern AP. Also, the first insulating layer 142, the second insulating layer 144, and the conductive layer 146 may be sequentially disposed on the gate insulating layer GI, the spacer 138, and the second gap-fill insulating layer 136.

The first vertical section 140a may include the first insulating layer 142, the second insulating layer 144, and the conductive layer 146. Also, the first vertical section 140a may further include an oxide film layer 143 located between the first insulating layer 142 and the second insulating layer 144. The oxide film layer 143 may be formed at the interface between the first insulating layer 142 and the second insulating layer 144. On the other hand, the second vertical section 140b, the first horizontal section 140c, and the second horizontal section 140d may each include the second insulating layer 144 and the conductive layer 146. The second vertical section 140b, the first horizontal section 140c, and the second horizontal section 140d may not include the first insulating layer 142 and the oxide film layer 143.

The first insulating layer 142 and the second insulating layer 144 may include silicon nitride, and the oxide film layer 143 may include silicon oxide. The conductive layer 146 includes polysilicon, but the inventive concept is not limited thereto. The conductive layer 146 may include, for example, the same material as the bit line BL.

In embodiments, the first vertical section 140a may have a first thickness t1, and the second vertical section 140b may have a second thickness t2. In this case, the first thickness t1 may be greater than the second thickness t2. The first vertical section 140a includes the first insulating layer 142, the oxide film layer 143, the second insulating layer 144, and the conductive layer 146, and the second vertical section 140b includes the second insulating layer 144 and the conductive layer 146. Accordingly, the first thickness t1 may be greater than the second thickness t2.

The vertical level of the upper surface of the lower separation structure 140 may be higher than or equal to the vertical level of the semiconductor pattern AP located lowermost among the plurality of semiconductor patterns AP. The lower separation structure 140 may insulate one or more semiconductor patterns AP from the bit line BL. Also, the lower separation structure 140 may insulate the bit line BL from the substrate 110. Although FIGS. 4 and 5 show that the vertical level of the upper surface of the lower separation structure 140 is the same as the vertical level of the semiconductor pattern AP located lowermost, the inventive concept is not limited thereto. Also, although not shown, the upper surfaces of a plurality of lower separation structures 140 adjacent to one another in the first horizontal direction X and the second horizontal direction Y may have the same vertical level.

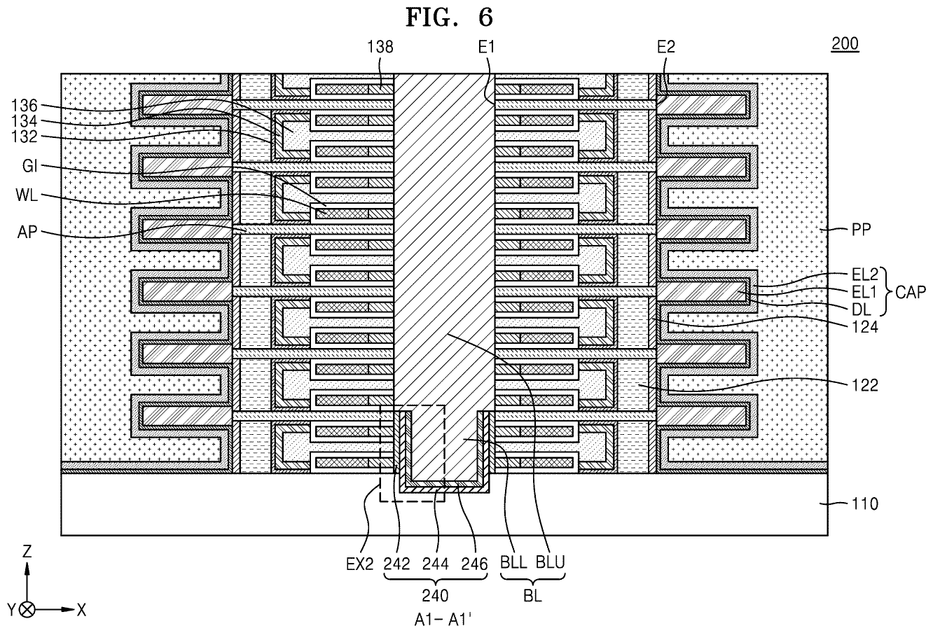

FIG. 6 is a cross-sectional view of a semiconductor device according to embodiments, in a region corresponding to the cross-section taken along line A1-A1′ of FIG. 3.

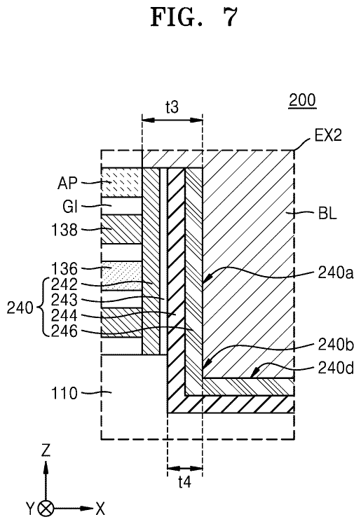

FIG. 7 is an enlarged cross-sectional view of region EX2 of FIG. 6.

When describing a semiconductor device 200 of FIGS. 6 and 7, descriptions of the same parts as the semiconductor device 100 described with reference to FIGS. 4 and 5 are omitted, and the differences therebetween are mainly described.

Referring to FIGS. 6 and 7, the semiconductor device 200 according to the inventive concept may include a lower separation structure 240. The lower separation structure 240 may partially pass through the substrate 110 in the vertical direction Z and be located between the substrate 110 and the bit line BL. The lower separation structure 240 may have a shape surrounding the lower end of the bit line BL and may extend in the second horizontal direction Y.

The bit line BL may include a lower region BLL and an upper region BLU. The lower region BLL may include a region in contact with the lower separation structure 240, and the upper region BLU may include a region that extends in the vertical direction Z on the lower region BLL and is in contact with the first ends E1 of the plurality of semiconductor patterns AP.

In embodiments, the width of the lower region BLL in the first horizontal direction X may be less than the width of the upper region BLU in the first horizontal direction X. In this case, the width of the lower region BLL in the first horizontal direction X may be constant.

The lower region BLL may cover the lower separation structure 240, and the bottom surface of the lower region BLL may have the same profile as the upper surface of the lower separation structure 240. For example, the bottom surface of the lower region BLL may cover the sidewalls and the upper surface of the lower separation structure 240.

In embodiments, the lower separation structure 240 may include a first vertical section 240a extending in the vertical direction Z above the substrate 110 and a second vertical section 240b extending in the vertical direction Z and partially passing through the substrate 110.

The first vertical section 240a may be located between the semiconductor pattern AP and the bit line BL and extend in the vertical direction Z. The first vertical section 240a may extend in the vertical direction Z above the substrate 110 so as to cover at least one of the semiconductor patterns AP. Also, the lower separation structure 240 may include a pair of first vertical sections 240a, and the upper surfaces of the pair of first vertical sections 240a may have the same vertical level. The second vertical section 240b may be located between the substrate 110 and the bit line BL and extend in the vertical direction Z.

The first vertical section 240a may overlap the second vertical section 240b in the vertical direction Z. The inner wall of the first vertical section 240a and the inner wall of the second vertical section 240b may be coplanar with one another and extend in the vertical direction Z.

The lower separation structure 240 may include a horizontal section 240d. The horizontal section 240d may be connected to one end of the second vertical section 240b and extend in the first horizontal direction X. The horizontal section 240d may connect the pair of second vertical sections 240b that are spaced apart from one another in the first horizontal direction X. The horizontal section 240d may cover the bottom surface of the bit line BL.

In embodiments, the lower separation structure 240 may include a first insulating layer 242, a second insulating layer 244, and a conductive layer 246. The first insulating layer 242, the second insulating layer 244, and the conductive layer 246 may be sequentially disposed on the semiconductor pattern AP. Also, the first insulating layer 242, the second insulating layer 244, and the conductive layer 246 may be sequentially disposed on the gate insulating layer GI, the spacer 138, and the second gap-fill insulating layer 136.

The first vertical section 240a may include the first insulating layer 242, the second insulating layer 244, and the conductive layer 246. Also, the first vertical section 240a may further include an oxide film layer 243 located between the first insulating layer 242 and the second insulating layer 244. The oxide film layer 243 may be formed at the interface between the first insulating layer 242 and the second insulating layer 244. On the other hand, the second vertical section 240b and the horizontal section 240d may each include the second insulating layer 244 and the conductive layer 246. The second vertical section 240b and the horizontal section 240d may not include the first insulating layer 242 and the oxide film layer 243.

The first insulating layer 242 and the second insulating layer 244 may include silicon nitride, and the oxide film layer 243 may include silicon oxide. The conductive layer 246 includes polysilicon, but the inventive concept is not limited thereto. The conductive layer 246 may include, for example, the same material as the bit line BL.

In embodiments, the first vertical section 240a may have a first thickness t3, and the second vertical section 240b may have a second thickness t4. In this case, the first thickness t3 may be greater than the second thickness t4. The first vertical section 240a includes the first insulating layer 242, the oxide film layer 243, the second insulating layer 244, and the conductive layer 246, and the second vertical section 240b includes the second insulating layer 244 and the conductive layer 246. Accordingly, the first thickness t3 may be greater than the second thickness t4.

The vertical level of the upper surface of the lower separation structure 240 may be higher than or equal to the vertical level of the semiconductor pattern AP located lowermost among the plurality of semiconductor patterns AP. The lower separation structure 240 may insulate one or more semiconductor patterns AP from the bit line BL. Also, the lower separation structure 240 may insulate the bit line BL from the substrate 110. Although FIGS. 6 and 7 show that the vertical level of the upper surface of the lower separation structure 240 is the same as the vertical level of the semiconductor pattern AP located lowermost, the inventive concept is not limited thereto. Also, although not shown, the upper surfaces of a plurality of lower separation structures 240 adjacent to one another in the first horizontal direction X and the second horizontal direction Y may have the same vertical level.

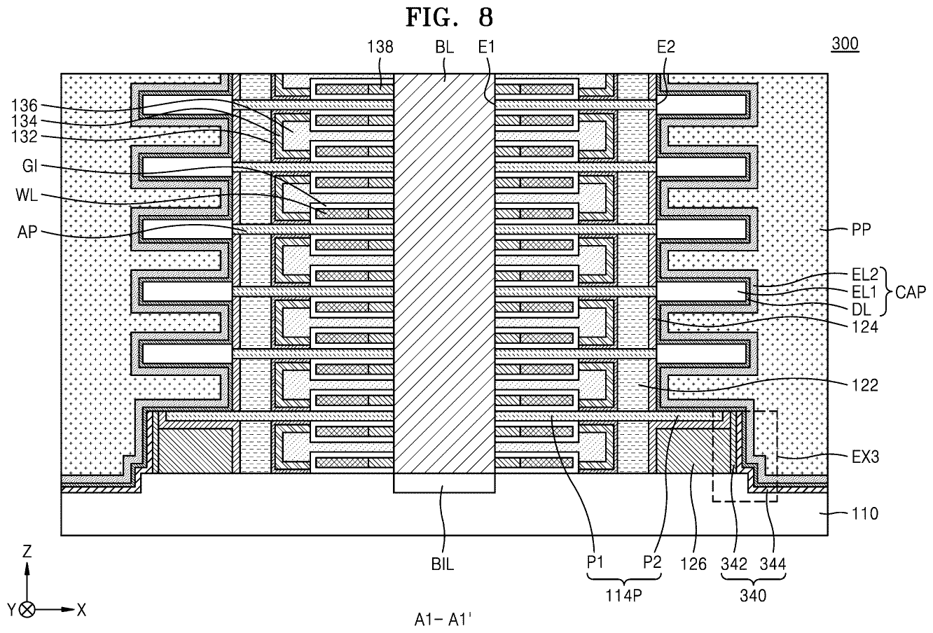

FIG. 8 is a cross-sectional view of a semiconductor device according to embodiments, in a region corresponding to the cross-section taken along line A1-A1′ of FIG. 3.

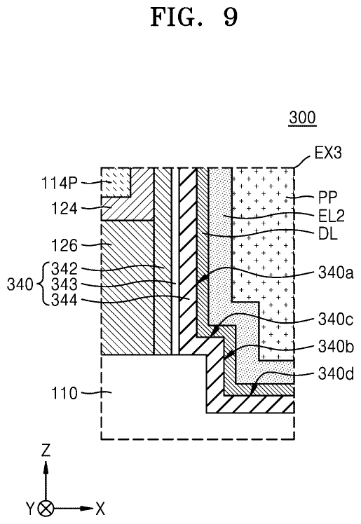

FIG. 9 is an enlarged cross-sectional view of region EX3 of FIG. 8.

When describing a semiconductor device 300 of FIGS. 8 and 9, descriptions of the same parts as the semiconductor device 100 described with reference to FIGS. 4 and 5 are omitted, and the differences therebetween are mainly described.

Referring to FIGS. 8 and 9, the semiconductor device 300 according to the inventive concept may include a lower separation structure 340. The lower separation structure 340 may include a first vertical section 340a extending in the vertical direction Z above the substrate 110 and a second vertical section 340b extending in the vertical direction Z and partially passing through the substrate 110.

The capacitor dielectric layer DL, the second electrode EL2, and the plate electrode PP may be sequentially disposed on the lower separation structure 340. The cell capacitor CAP, including the capacitor dielectric layer DL and the second electrode EL2 disposed on the lower separation structure 340, may be connected to the plate electrode PP.

The first vertical section 340a may be located between the semiconductor pattern AP and the plate electrode PP and extend in the vertical direction Z. The first vertical section 340a may extend in the vertical direction Z above the substrate 110 so as to cover at least one of the semiconductor patterns AP.

Specifically, the first vertical section 340a may partially cover the semiconductor pattern AP, the first insulating liner 124, and a third gap-fill insulating layer 126. The second vertical section 340b may be located between the substrate 110 and the plate electrode PP and extend in the vertical direction Z. Although not shown, the lower separation structure 340 may include a pair of first vertical sections 340a spaced apart from one another in the first horizontal direction X with the plate electrode PP therebetween, and the upper surfaces of the pair of first vertical sections 340a may have the same vertical level.

The lower separation structure 340 may include a first horizontal section 340c and a second horizontal section 340d. The first horizontal section 340c may be located between the first vertical section 340a and the second vertical section 340b and extend in the first horizontal direction X. The first horizontal section 340c may connect the first vertical section 340a to the second vertical section 340b. Accordingly, the first vertical section 340a may not overlap the second vertical section 340b in the vertical direction Z. That is, the lower separation structure 340 may have a shape including a stepped region. However, the inventive concept is not limited thereto. As shown in the lower separation structure 240 of FIGS. 6 and 7, the first vertical section 340a may overlap the second vertical section 340b in the vertical direction Z.

The second horizontal section 340d may be connected to one end of the second vertical section 340b and extend in the first horizontal direction X. Although not shown, the second horizontal section 340d may connect a pair of second vertical sections 340b to one another, which are spaced apart from one another in the first horizontal direction X with the plate electrode PP therebetween. In this case, the upper surfaces of the pair of second vertical sections 340b may have the same vertical level. The second horizontal section 340d may cover the bottom surface of the plate electrode PP.

In embodiments, the lower separation structure 340 may include a first insulating layer 342 and a second insulating layer 344. The first insulating layer 342 and the second insulating layer 344 may be sequentially disposed on the first insulating liner 124 and the third gap-fill insulating layer 126.

The first vertical section 340a may include the first insulating layer 342 and the second insulating layer 344. Also, the first vertical section 340a may further include an oxide film layer 343 located between the first insulating layer 342 and the second insulating layer 344. The oxide film layer 343 may be formed at the interface between the first insulating layer 342 and the second insulating layer 344. On the other hand, the second vertical section 340b, the first horizontal section 340c, and the second horizontal section 340d may each include the second insulating layer 344. The second vertical section 340b, the first horizontal section 340c, and the second horizontal section 340d may not include the first insulating layer 342 and the oxide film layer 343. In this case, the first insulating layer 342 and the second insulating layer 344 may include silicon nitride, and the oxide film layer 343 may include silicon oxide.

The first vertical section 340a includes the first insulating layer 342, the oxide film layer 343, and the second insulating layer 344, and the second vertical section 340b includes the second insulating layer 344. Accordingly, the thickness of the first vertical section 340a may be greater than the thickness of the second vertical section 340b.

The vertical level of the upper surface of the lower separation structure 340 may be higher than or equal to the vertical level of the semiconductor pattern AP located lowermost among the plurality of semiconductor patterns AP. The lower separation structure 340 may insulate one or more semiconductor patterns AP from the plate electrode PP. Also, the lower separation structure 340 may insulate the plate electrode PP from the substrate 110.

In embodiments, the bit line BL may be connected to the first ends E1 of the plurality of semiconductor patterns AP. The bit lines BL may each extend in the vertical direction Z above the substrate 110 and may be spaced apart from one another in the second horizontal direction Y. A bit line separation insulating layer BIL may be located between the bit line BL and the substrate 110.

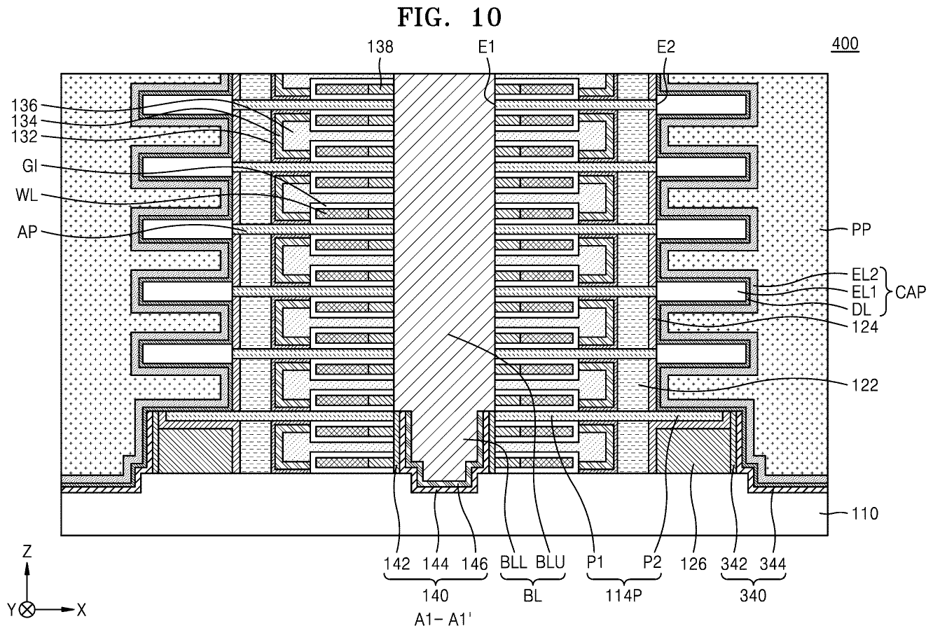

FIG. 10 is a cross-sectional view of a semiconductor device according to embodiments, in a region corresponding to the cross-section taken along line A1-A1′ of FIG. 3.

Referring to FIG. 10, a semiconductor device 400 according to the inventive concept may include the lower separation structure 140 (or referred to as a first lower separation structure 140) and the lower separation structure 340 (or referred to as a second lower separation structure 340). The first lower separation structure 140 may be substantially the same as the lower separation structure 140 of the semiconductor device 100 described above with reference to FIGS. 4 and 5. The second lower separation structure 340 may be substantially the same as the lower separation structure 340 of the semiconductor device 300 described above with reference to FIGS. 8 and 9.

In embodiments, the first lower separation structure 140 and the second lower separation structure 340 may be spaced apart from one another in the first horizontal direction X. The first lower separation structure 140 and the second lower separation structure 340 may be spaced apart from one another in the first horizontal direction X with the word line WL and a semiconductor layer pattern 114P therebetween. Also, the vertical level of the upper surface of the first lower separation structure 140 may be the same as the vertical level of the upper surface of the second lower separation structure 340, but the inventive concept is not limited thereto.

The first lower separation structure 140 may partially surround the lower end of the bit line BL and insulate the bit line BL from the substrate 110. Also, the second lower separation structure 340 may partially surround the lower end of the plate electrode PP and insulate the plate electrode PP from the substrate 110.

The shapes of the first lower separation structure 140 and the second lower separation structure 340 are not limited to those shown in FIG. 10. For example, at least one lower separation structure among the first lower separation structure 140 and the second lower separation structure 340 may have substantially the same shape as the lower separation structure 240 of the semiconductor device 200 described above with reference to FIGS. 6 and 7.

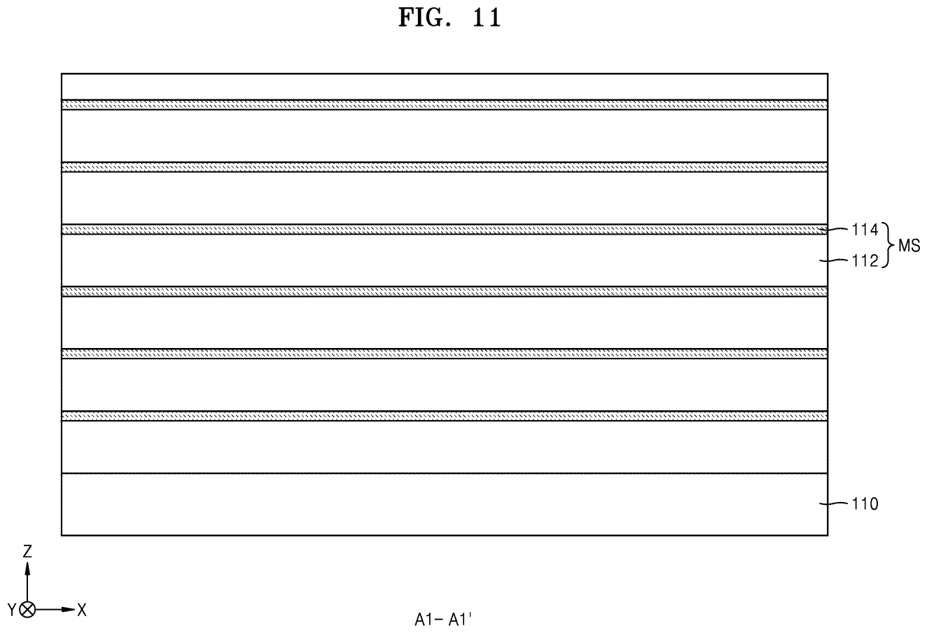

FIGS. 11 to 27 are cross-sectional views showing a method of manufacturing a semiconductor device, according to embodiments.

Referring to FIG. 11, a mold stack MS may be formed by alternately and sequentially forming a sacrificial mold layer 112 and a semiconductor layer 114 on the substrate 110.

In embodiments, the sacrificial mold layer 112 and the semiconductor layer 114 may include materials having an etch selectivity with respect to one another. For example, the sacrificial mold layer 112 and the semiconductor layer 114 may each include a single crystalline layer of a group IV semiconductor, a group IV-IV compound semiconductor, or a group III-V compound semiconductor, and the sacrificial mold layer 112 and the semiconductor layer 114 may include different materials. For example, the sacrificial mold layer 112 may include SiGe, and the semiconductor layer 114 may include single crystalline silicon. The sacrificial mold layer 112 and the semiconductor layer 114 may each have a thickness of several tens of nm.

In embodiments, the sacrificial mold layer 112 and the semiconductor layer 114 may be formed by an epitaxy process. For example, the epitaxy process may include vapor-phase epitaxy (VPE), chemical vapor deposition (CVD), such as ultra-high vacuum (UHV) CVD, molecular beam epitaxy, or a combination thereof. In the epitaxy process, a liquid or gaseous precursor may be used as a precursor required to form the sacrificial mold layer 112 and the semiconductor layer 114.

In embodiments, the thickness of the semiconductor layer 114 in the vertical direction Z may be less than the thickness of the sacrificial mold layer 112 in the vertical direction Z. In some embodiments, the thickness of the semiconductor layer 114 in the vertical direction Z may be substantially the same as the height of the semiconductor pattern AP which is formed in a subsequent process.

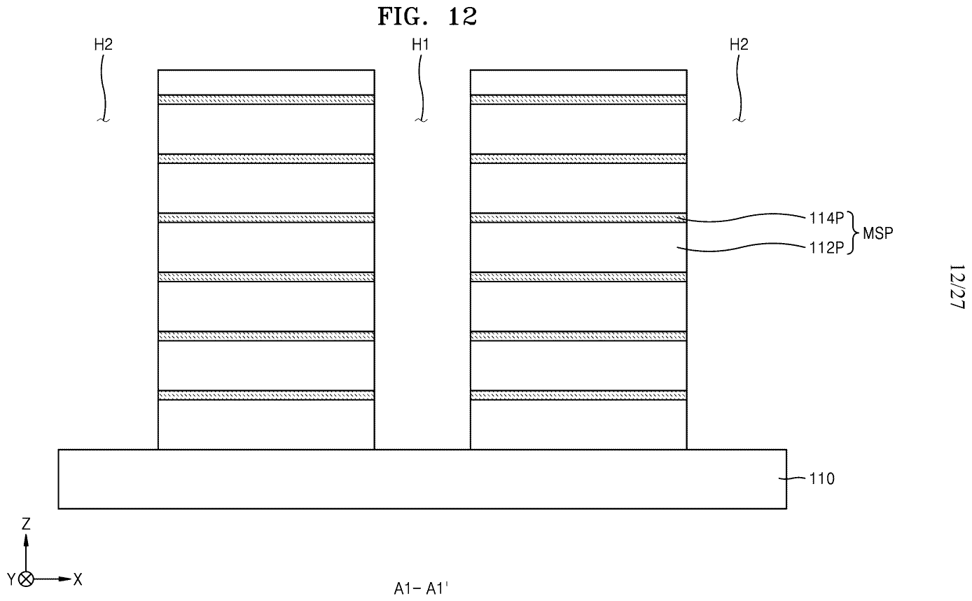

Referring to FIG. 12, a mask pattern (not shown) is formed on the mold stack MS, and the mold stack MS is partially removed by using the mask pattern as an etching mask, thereby forming a mold stack pattern MSP in which a plurality of semiconductor layer patterns 114P and a plurality of sacrificial mold layer patterns 112P are alternately stacked. The plurality of semiconductor layer patterns 114P and the plurality of sacrificial mold layer patterns 112P are arranged at positions overlapping one another in the vertical direction Z and may extend in the first horizontal direction X. As the mold stack pattern MSP is formed by partially removing the mold stack MS, a first hole H1 and a second hole H2 may be formed in the substrate 110.

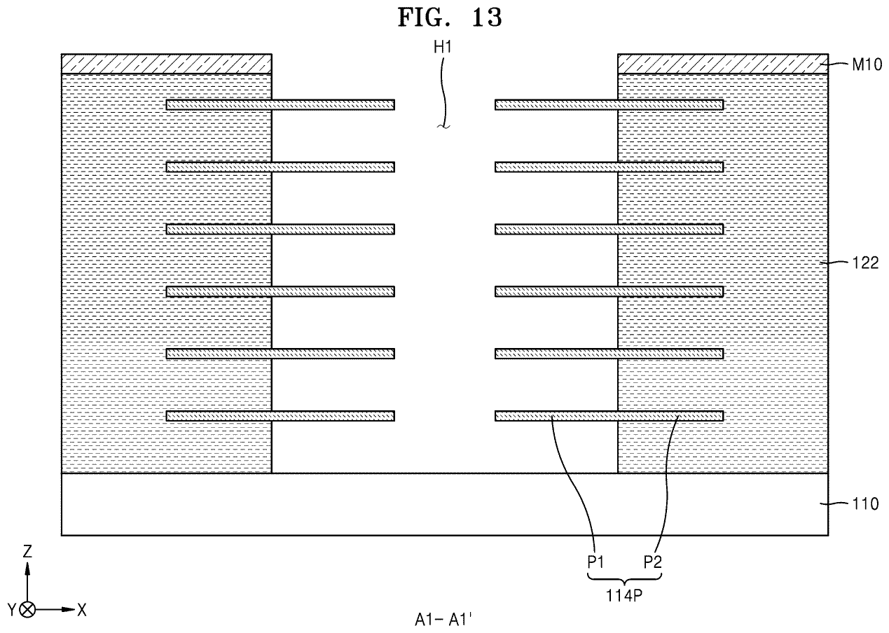

Referring to FIG. 13, the plurality of sacrificial mold layer patterns 112P may be removed. Also, in a region in which the sacrificial mold layer patterns 112P have been removed, the first gap-fill insulating layer 122 may be formed by using an insulating material. In this case, the first gap-fill insulating layer 122 may fill the second hole H2.

In embodiments, a process of removing the plurality of sacrificial mold layer patterns 112P may include a wet etching process or a pull-back process. For example, the process of removing the plurality of sacrificial mold layer patterns 112P may include an etching process that utilizes the etch selectivity between the sacrificial mold layer patterns 112P and the plurality of semiconductor layer patterns 114P. For example, during the wet etching process or the pull-back process, the etch rate of the plurality of semiconductor layer patterns 114P may be relatively low, and the etch rate of the plurality of sacrificial mold layer patterns 112P may be relatively high.

Subsequently, a first mask pattern M10 is formed on the first gap-fill insulating layer 122. Each of the plurality of semiconductor layer patterns 114P may include a first section P1 and a second section P2, and the first mask pattern M10 may vertically overlap the second sections P2 of the plurality of semiconductor layer patterns 114P.

Subsequently, the first gap-fill insulating layer 122 not covered by the first mask pattern M10 may be partially removed to expose the first sections P1 of the plurality of semiconductor layer patterns 114P. The second sections P2 of the plurality of semiconductor layer patterns 114P may be covered by the first gap-fill insulating layer 122 and thus not exposed to the outside. In embodiments, the process of partially removing the first gap-fill insulating layer 122 may include a lateral recess process or a pull-back process.

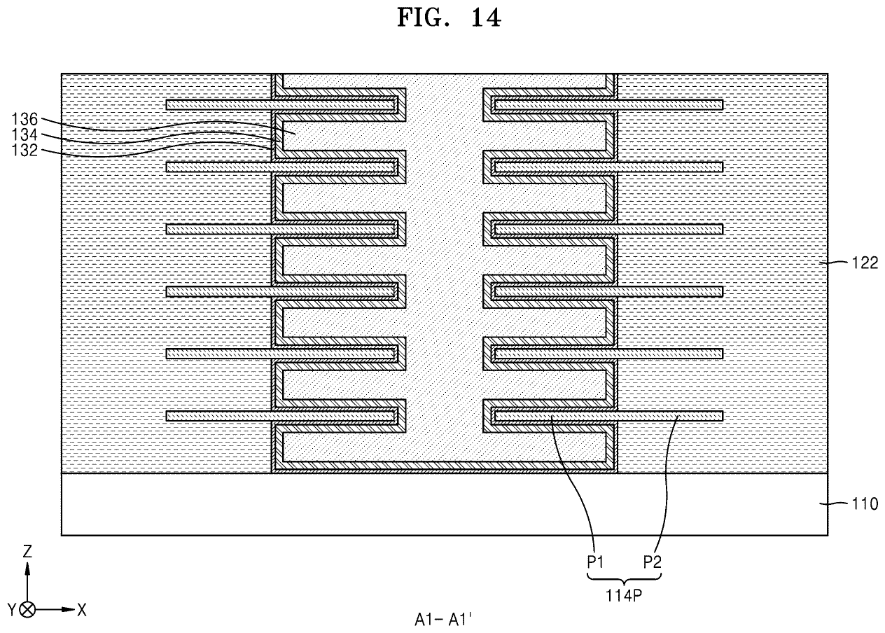

Referring to FIG. 14, the second insulating liner 132, the third insulating liner 134, and the second gap-fill insulating layer 136 may be sequentially formed, via the first hole H1, on the upper surfaces, the bottom surfaces, and the sidewalls of the first sections P1 of the plurality of semiconductor layer patterns 114P. In embodiments, the second insulating liner 132, the third insulating liner 134, and the second gap-fill insulating layer 136 may be formed by using at least one of silicon oxide, silicon nitride, and silicon oxynitride. In embodiments, the second insulating liner 132 and the second gap-fill insulating layer 136 may include silicon oxide, and the third insulating liner 134 may include silicon nitride. In this case, the third insulating liner 134 may fill the first hole H1.

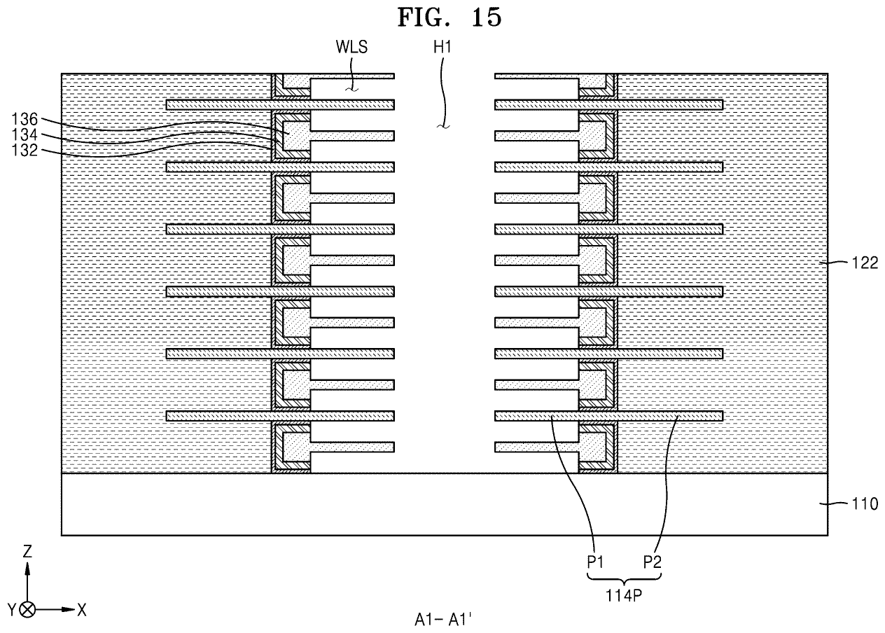

Referring to FIG. 15, the second gap-fill insulating layer 136 may be partially removed to expose the sidewall of the second insulating liner 132, and the second insulating liner 132 and the third insulating liner 134 may be removed laterally by a certain length. Accordingly, the first sections P1 of the semiconductor layer pattern 114P may be exposed again. The second gap-fill insulating layer 136 may partially protrude between two first sections P1 adjacent to one another in the vertical direction Z, and a word line space WLS may be formed between the protruding part of the second gap-fill insulating layer 136 and the first section P1.

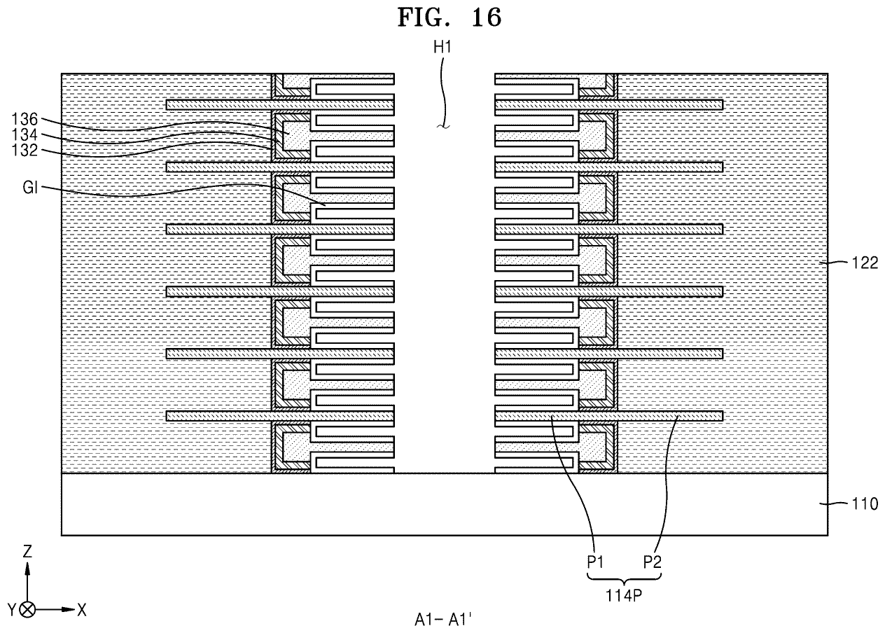

Referring to FIG. 16, the gate insulating layer GI may be formed on the inner wall of the word line space WLS. In embodiments, the gate insulating layer GI disposed on the sidewall of the first section P1 of the semiconductor layer pattern 114P may be partially removed by an etching process, and thus, the sidewall of the first section P1 may be exposed again.

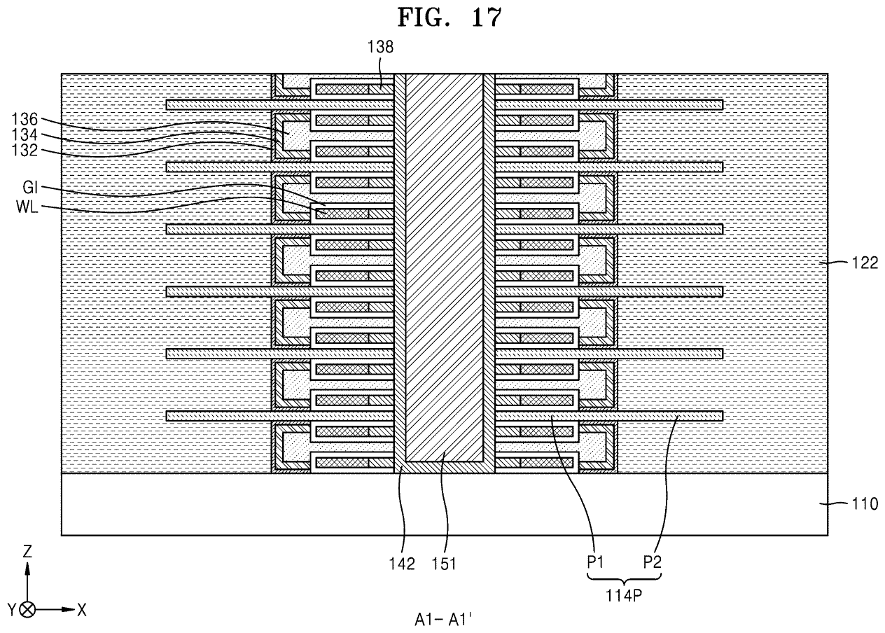

Referring to FIG. 17, the word line WL may be formed on the inner wall of the word line space WLS (see FIG. 16). Subsequently, the word line WL may be partially removed from an entrance of the word line space WLS, and thus, the remainder of the word line WL may be left inside the word line space WLS. The process of partially removing the word line WL may include a lateral recess process or a pull-back process.

Subsequently, the spacer 138 may fill the remaining region of the word line space WLS. In embodiments, the spacer 138 may be formed by using at least one of silicon oxide, silicon nitride, and silicon oxynitride.

Subsequently, the first insulating layer 142 and a fourth gap-fill insulating layer 151 may fill the first hole H1. In this case, the first insulating layer 142 may include silicon nitride, and the fourth gap-fill insulating layer 151 may include silicon oxide. In another embodiment, the first insulating layer 142 may be formed integrally with the spacer 138.

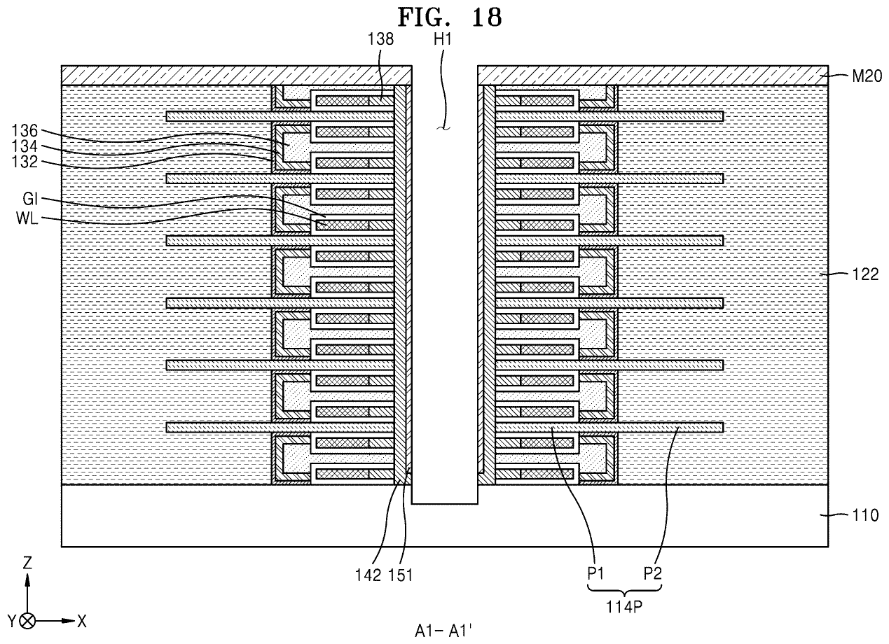

Referring to FIG. 18, a second mask pattern M20 may be formed on the resulting structure of FIG. 17. The first insulating layer 142 and the fourth gap-fill insulating layer 151 may be removed by using the second mask pattern M20 as an etching mask. The first insulating layer 142 and the fourth gap-fill insulating layer 151 may be removed by an etching process to form the first hole H1. The first hole H1 may pass through the fourth gap-fill insulating layer 151 in the vertical direction Z. In addition, the substrate 110 may be partially removed by the etching process.

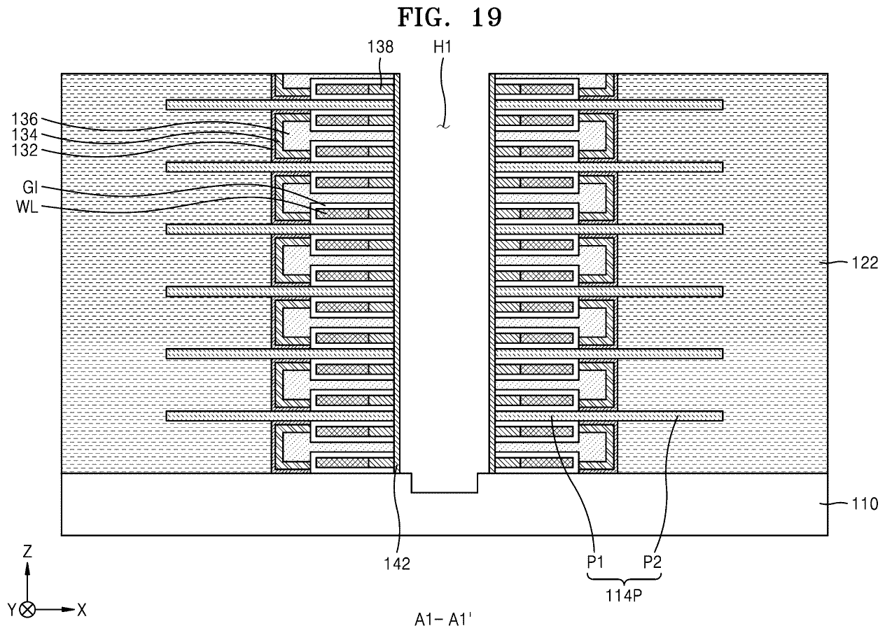

Referring to FIG. 19, the fourth gap-fill insulating layer 151 may be removed from the resulting structure of FIG. 18. As the fourth gap-fill insulating layer 151 is removed, the first insulating layer 142 may be exposed via the first hole H1. The process of removing the fourth gap-fill insulating layer 151 may be performed by a wet etching process. The first insulating layer 142 may be partially removed by the wet etching process. As the first insulating layer 142 is partially removed and reduced in thickness, the width of the first hole H1 may increase. The fourth gap-fill insulating layer 151 and part of the first insulating layer 142 may be removed, and thus, the size of the first hole H1 may increase.

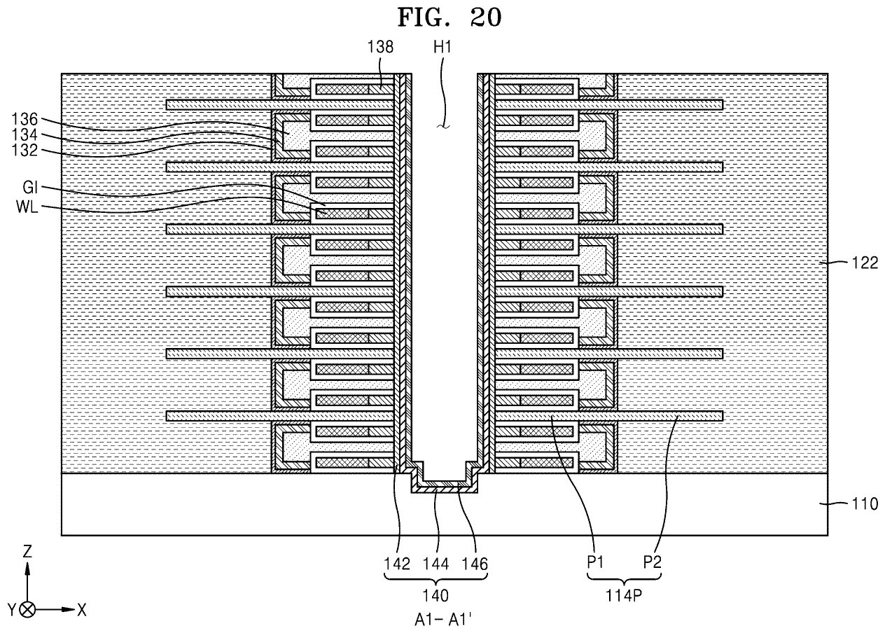

Referring to FIG. 20, the second insulating layer 144 and the conductive layer 146 may be sequentially formed on the first insulating layer 142 and the substrate 110. The second insulating layer 144 and the conductive layer 146 may conformably cover the first insulating layer 142. The second insulating layer 144 and the conductive layer 146 may sequentially cover the upper surface of the substrate 110, which is exposed via the first hole H1.

In embodiments, the second insulating layer 144 may include silicon nitride, and the conductive layer 146 may include polysilicon. However, the inventive concept is not limited thereto. In this case, the oxide film layer 143 (see FIG. 5) may be formed at the interface between the first insulating layer 142 and the second insulating layer 144. During the process, the oxide film layer 143 may be formed spontaneously on the first insulating layer 142, and the second insulating layer 144 may cover the oxide film layer 143.

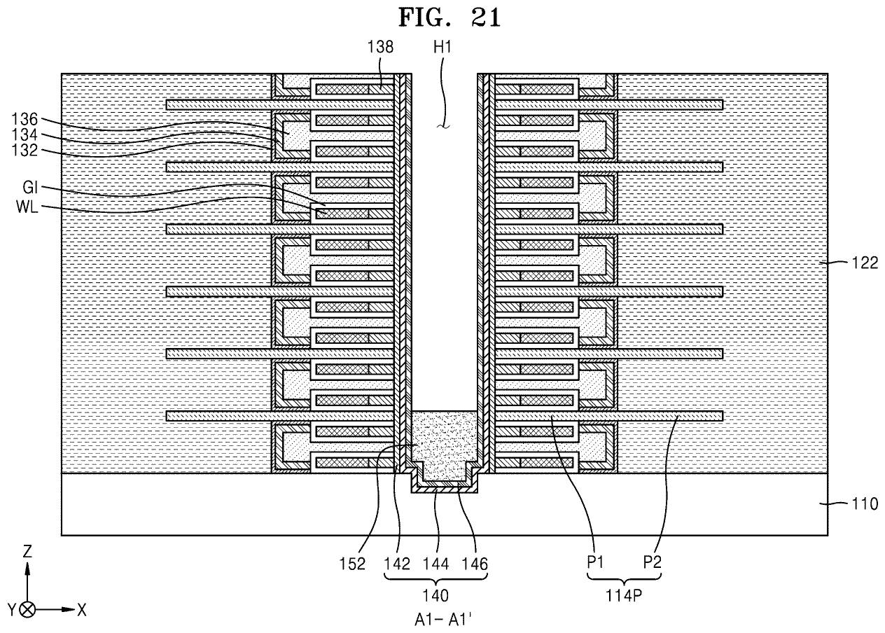

Referring to FIG. 21, a gap-fill dielectric layer 152 may partially fill the first hole H1. The gap-fill dielectric layer 152 may partially cover the conductive layer 146. The gap-fill dielectric layer 152 may be formed such that the vertical level of the upper surface of the gap-fill dielectric layer 152 is higher than or equal to the vertical level of the upper surface of the semiconductor layer pattern 114P located lowermost. FIG. 21 shows that the gap-fill dielectric layer 152 covers only the semiconductor layer pattern 114P located lowermost, but the inventive concept is not limited thereto. For example, the gap-fill dielectric layer 152 may cover two or more semiconductor layer patterns 114P arranged in the vertical direction Z.

In addition, although not shown, the upper surfaces of a plurality of gap-fill dielectric layers 152 respectively filling a plurality of first holes H1 adjacent to one another in the first horizontal direction X and the second horizontal direction Y may have the same vertical level.

In embodiments, the gap-fill dielectric layer 152 may include carbon (C), but the inventive concept is not limited thereto. In another embodiment, the gap-fill dielectric layer 152 may include flowable oxide. In this case, the gap-fill dielectric layer 152 may be formed by a flowable chemical vapor deposition (F-CVD) process.

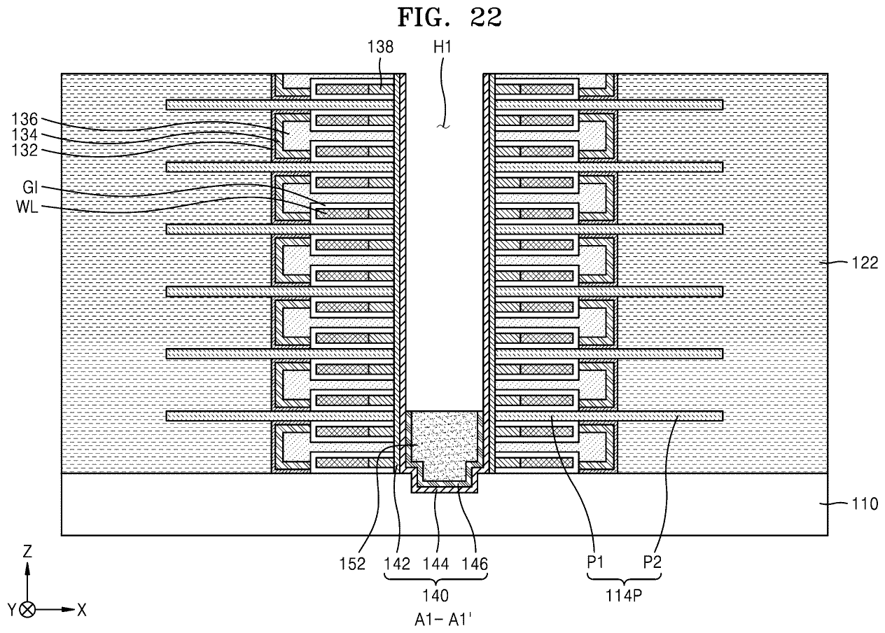

Referring to FIG. 22, the conductive layer 146 may be partially removed. The conductive layer 146, which is not covered by the gap-fill dielectric layer 152 and exposed via the first hole H1, may be removed. Accordingly, the vertical level of the upper surface of the conductive layer 146 may be the same as the vertical level of the upper surface of the gap-fill dielectric layer 152. In this case, the conductive layer 146 may be removed by a strip process, but the inventive concept is not limited thereto.

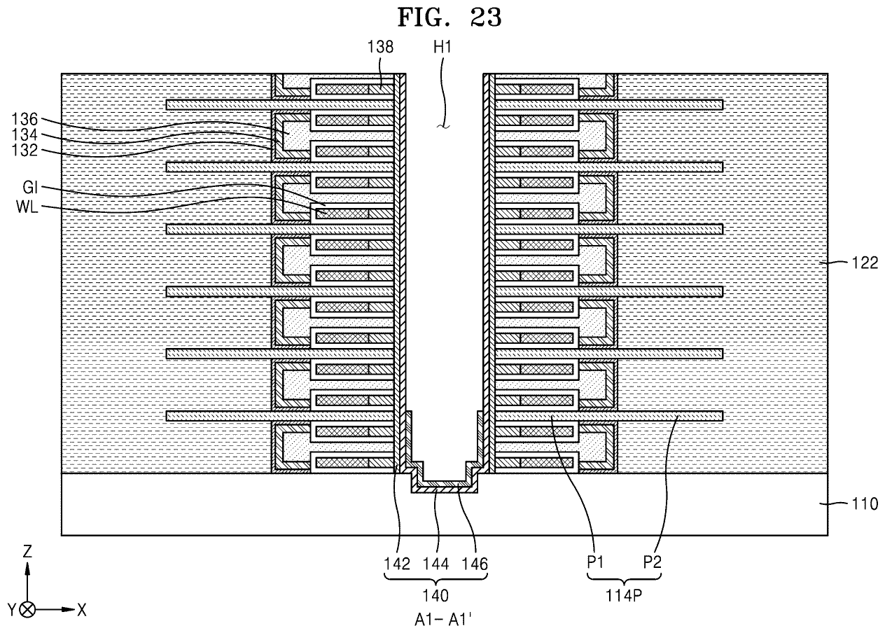

Referring to FIG. 23, the gap-fill dielectric layer 152 may be removed. As the gap-fill dielectric layer 152 is removed, both the upper surface and the sidewall of the conductive layer 146 may be exposed. In this case, the gap-fill dielectric layer 152 may be removed by a strip process, but the inventive concept is not limited thereto.

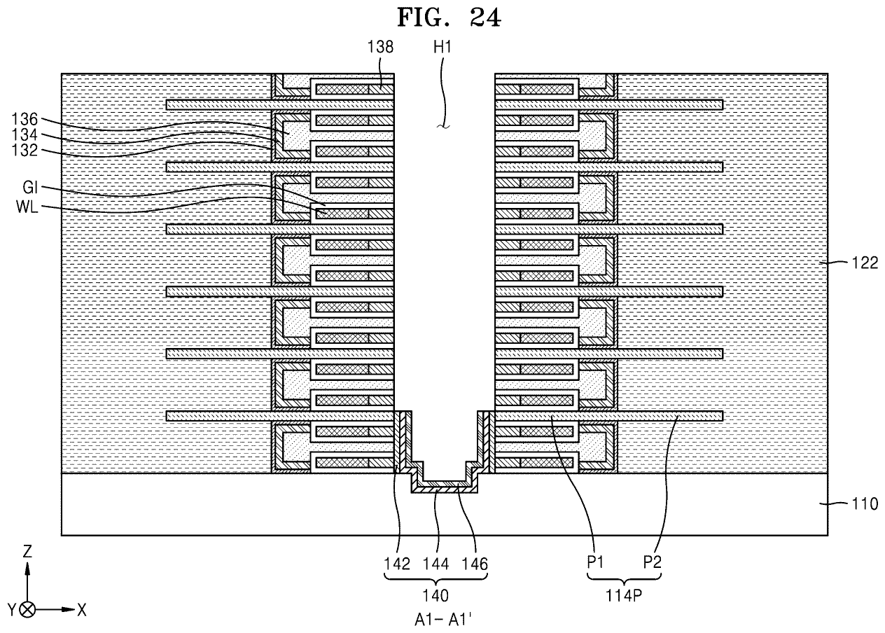

Referring to FIG. 24, the lower separation structure 140 may be formed by partially removing the first insulating layer 142 and the second insulating layer 144. The first insulating layer 142 and the second insulating layer 144, which are not covered by the conductive layer 146 and are exposed via the first hole H1, may be removed. Accordingly, the vertical level of the upper surface of each of the first insulating layer 142 and the second insulating layer 144 may be the same as the vertical level of the upper surface of the conductive layer 146. Also, although not shown, the upper surfaces of the plurality of lower separation structures 140 adjacent to one another in the first horizontal direction X and the second horizontal direction Y may have the same vertical level. In this case, the first insulating layer 142 and the second insulating layer 144 may be removed by a strip process and/or a wet etching process, but the inventive concept is not limited thereto.

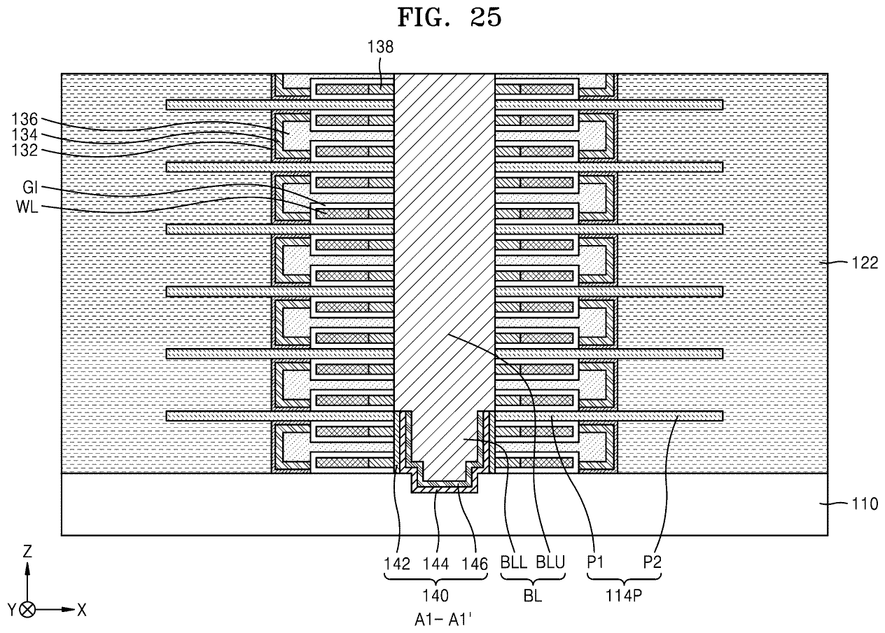

Referring to FIG. 25, the bit line BL may be connected to the semiconductor layer pattern 114P and extend in the vertical direction Z. The bit line BL may be electrically connected to the first sections P1 (see FIG. 4) of the plurality of semiconductor layer patterns 114P. The bit line BL may fill the first hole H1 while covering the lower separation structure 140. In this case, due to the lower separation structure 140, the semiconductor layer pattern 114P located lowermost may not be connected to the bit line BL.

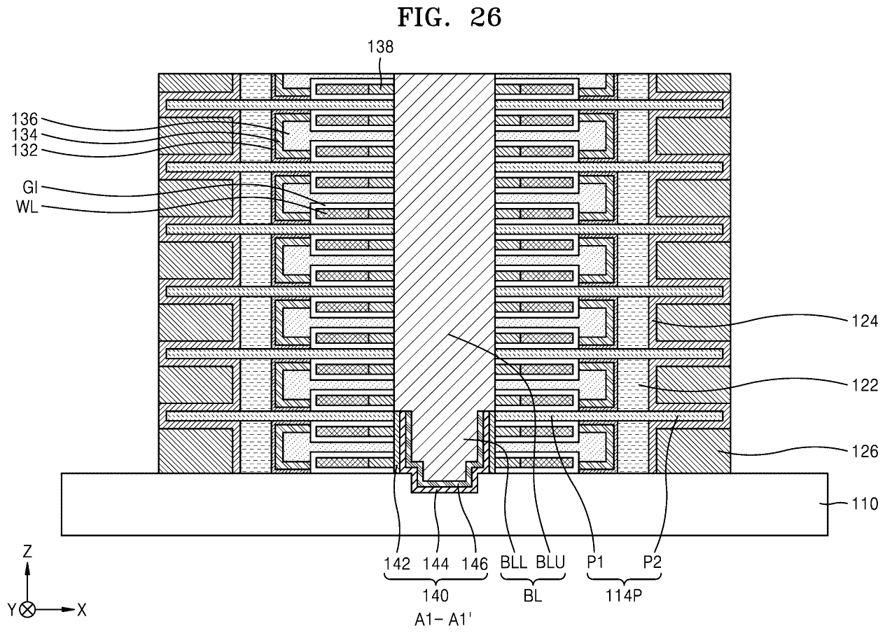

Referring to FIG. 26, a mask pattern may be formed on the first gap-fill insulating layer 122, and the first gap-fill insulating layer 122 may be partially removed by using the mask pattern as an etching mask. Accordingly, the second sections P2 of the plurality of semiconductor layer patterns 114P may be partially exposed. In embodiments, the process of partially removing the first gap-fill insulating layer 122 may include a lateral recess process or a pull-back process.

Subsequently, the first insulating liner 124 and the third gap-fill insulating layer 126 may be sequentially formed on the second sections P2 of the plurality of semiconductor layer patterns 114P. The first insulating liner 124 may be conformally disposed on the sidewalls of the first gap-fill insulating layer 122 and on the exposed surfaces of the second sections P2 of the plurality of semiconductor layer patterns 114P, and the third gap-fill insulating layer 126 may be provided on the first insulating liner 124 and surround the second sections P2 of the plurality of semiconductor layer patterns 114P.

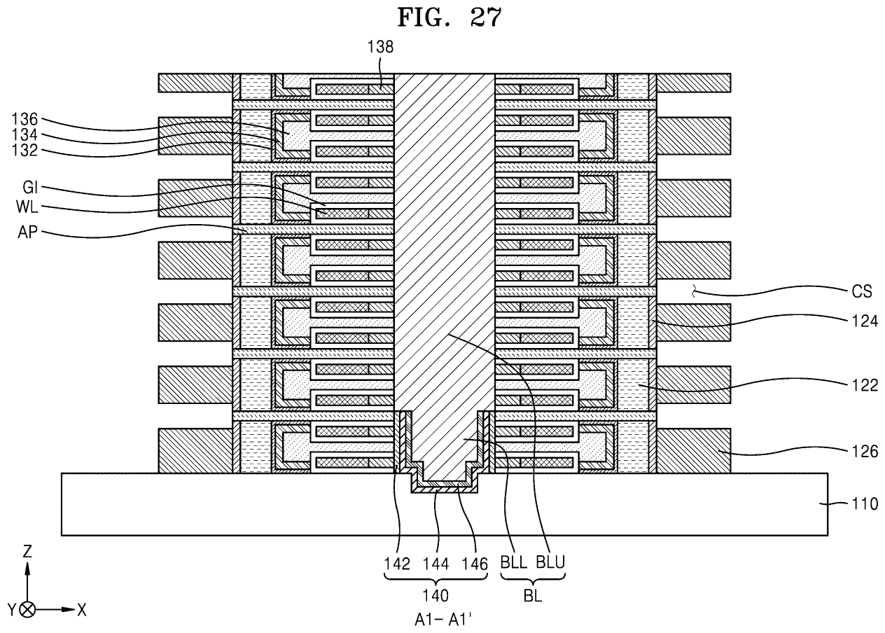

Referring to FIG. 27, the second sections P2 of the plurality of semiconductor layer patterns 114P are removed, and then, the first insulating liner 124 is partially removed. Accordingly, a plurality of capacitor spaces CS may be formed. In embodiments, the plurality of capacitor spaces CS may be arranged at positions respectively corresponding to the plurality of semiconductor layer patterns 114P and may be spaced apart from one another, for example, in the vertical direction Z and the second horizontal direction Y.

In this case, regions of the plurality of semiconductor layer patterns 114P, which remain after the second sections P2 of the plurality of semiconductor layer patterns 114P are removed, may be referred to as the semiconductor patterns AP. The second end E2 of the semiconductor pattern AP may be exposed in the capacitor space CS.

Referring back to FIG. 4, the first electrodes EL1 may be formed inside the plurality of capacitor spaces CS. The first electrodes EL1 may fill the plurality of capacitor spaces CS and extend in the first horizontal direction X. Subsequently, the third gap-fill insulating layer 126 may be removed.

Subsequently, the capacitor dielectric layer DL and the second electrode EL2 may be sequentially formed on the surface of the first electrode EL1 to form the cell capacitor CAP. In embodiments, the capacitor dielectric layer DL may be disposed on the first electrode EL1 and, for example, may be conformally disposed on the upper surface, the bottom surface, and the sidewall of the first electrode EL1. The second electrode EL2 may be disposed on the capacitor dielectric layer DL and may be conformally disposed on the upper surface, the bottom surface, and the sidewall of the capacitor dielectric layer DL.

Subsequently, the plate electrode PP may be formed on the cell capacitor CAP (e.g., on the surface of the second electrode EL2). In embodiments, at least a portion of the plate electrode PP may fill the space between two adjacent cell capacitors CAP (e.g., the space between two cell capacitors CAP adjacent to one another in the second horizontal direction Y and/or the space between two cell capacitors CAP adjacent to one another in the vertical direction Z).

In the method of manufacturing the semiconductor device 100, according to the embodiments, the lower separation structure 140 including the first insulating layer 142, the second insulating layer 144, and the conductive layer 146 may be formed by the process of depositing and removing the gap-fill dielectric layer 152. Through the process of depositing and removing the gap-fill dielectric layer 152, the lower separation structure 140 may be formed. Also, the bit line BL may be formed on the lower separation structure 140 so that the bit line BL is insulated from the substrate 110. In the method of manufacturing the semiconductor device 100, according to the inventive concept, the first hole H1 partially passing through the substrate 110 is formed by a full etching process (see FIG. 18), and the lower separation structure 140 is formed separately. Accordingly, distribution defects due to voids or seams generated during a partial etching process may be prevented. Therefore, the reliability of the semiconductor device 100 may be improved.

In another embodiment, when the fourth gap-fill insulating layer 151 is completely removed in the process of FIG. 18, the process of FIG. 19 may be omitted. In this case, as shown in the semiconductor device 200 of FIGS. 6 and 7, the lower separation structure 240 may not have a stepped region. That is, the first vertical section 240a may overlap the second vertical section 240b in the vertical direction Z. The inner wall of the first vertical section 240a and the inner wall of the second vertical section 240b may be coplanar with one another and extend in the vertical direction Z.

In another embodiment, processes similar to those described with reference to FIGS. 18 to 24 may be performed on the resulting structure of FIG. 26 to form the lower separation structure 340 of FIGS. 8 to 10. After the lower separation structure 340 is formed, the plurality of cell capacitors CAP and the plate electrode PP may be formed on the lower separation structure 340.

While the inventive concept has been particularly shown and described with reference to embodiments thereof, it will be understood that various changes in form and details may be made therein without departing from the spirit and scope of the following claims.

What is claimed is:

1. A semiconductor device comprising:
a substrate;
a plurality of semiconductor patterns extending in a first horizontal direction, above the substrate, and spaced apart from one another in a second horizontal direction and a vertical direction, which intersect the first horizontal direction, the plurality of semiconductor patterns each comprising a first end and a second end;
a bit line connected to the first ends of the plurality of semiconductor patterns and extending in the vertical direction;
a plurality of word lines extending in the second horizontal direction, above the plurality of semiconductor patterns; and
a lower separation structure partially passing through the substrate in the vertical direction and located between the substrate and the bit line, the lower separation structure extending above the substrate to cover at least one semiconductor pattern.

2. The semiconductor device of claim 1, wherein the lower separation structure comprises:
a first vertical section located between the at least one semiconductor pattern and the bit line and extending in the vertical direction; and
a second vertical section located between the substrate and the bit line and extending in the vertical direction.

3. The semiconductor device of claim 2, wherein the first vertical section of the lower separation structure has a first thickness, and
the second vertical section of the lower separation structure has a second thickness that is less than the first thickness of the lower separation structure.

4. The semiconductor device of claim 3, wherein the first vertical section and the second vertical section of the lower separation structure do not overlap one another in the vertical direction, and
the lower separation structure further comprises a first horizontal section that is located between the first vertical section and the second vertical section of the lower separation structure and extends in the first horizontal direction.

5. The semiconductor device of claim 3, wherein the first vertical section and the second vertical section of the lower separation structure overlap one another in the vertical direction.

6. The semiconductor device of claim 2, wherein the lower separation structure comprises a first insulating layer, a second insulating layer, and a conductive layer, which are sequentially disposed on the at least one semiconductor pattern.

7. The semiconductor device of claim 6, wherein the first insulating layer and the second insulating layer comprise silicon nitride, and
the first vertical section of the lower separation structure further comprises an oxide film layer located between the first insulating layer and the second insulating layer.

8. The semiconductor device of claim 1, wherein a vertical level of an upper surface of the lower separation structure is higher than or equal to a vertical level of an upper surface of a semiconductor pattern located lowermost among the plurality of semiconductor patterns.

9. The semiconductor device of claim 1, wherein the bit line comprises a lower region, which is in contact with the lower separation structure, and an upper region, which is disposed on the lower region and in contact with the first ends of the plurality of semiconductor patterns, and
a width of the lower region of the bit line in the first horizontal direction is less than a width of the upper region of the bit line in the first horizontal direction.

10. The semiconductor device of claim 9, wherein the lower region of the bit line comprises a first lower region passing through the substrate and a second lower region disposed on the first lower region, and
a width of the first lower region of the bit line in the first horizontal direction is less than a width of the second lower region of the bit line in the first horizontal direction.

11. A semiconductor device comprising:
a substrate;
a plurality of semiconductor patterns extending in a first horizontal direction, above the substrate, and spaced apart from one another in a second horizontal direction and a vertical direction, which intersect the first horizontal direction, the plurality of semiconductor patterns each comprising a first end and a second end;
a bit line connected to the first ends of the plurality of semiconductor patterns and extending in the vertical direction;
a plurality of word lines extending in the second horizontal direction, above the plurality of semiconductor patterns;
a plurality of cell capacitors respectively connected to the second ends of the plurality of semiconductor patterns;
a plate electrode connected to the plurality of cell capacitors and extending in the vertical direction; and
a first lower separation structure partially passing through the substrate in the vertical direction and located between the substrate and the plate electrode, the first lower separation structure extending above the substrate to cover at least one semiconductor pattern.

12. The semiconductor device of claim 11, wherein the first lower separation structure comprises:
a first vertical section located between the at least one semiconductor pattern and the plate electrode and extending in the vertical direction; and
a second vertical section located between the substrate and the plate electrode and extending in the vertical direction.

13. The semiconductor device of claim 12, wherein the first vertical section of the first lower separation structure has a first thickness, and
the second vertical section of the first lower separation structure has a second thickness that is less than the first thickness of the first lower separation structure.

14. The semiconductor device of claim 13, wherein the first vertical section and the second vertical section of the first lower separation structure do not overlap one another in the vertical direction, and
the first lower separation structure further comprises a first horizontal section that is located between the first vertical section and the second vertical section of the first lower separation structure and extends in the first horizontal direction.

15. The semiconductor device of claim 12, wherein the first lower separation structure comprises a first insulating layer and a second insulating layer, which are sequentially disposed on the at least one semiconductor pattern, and
the first vertical section of the first lower separation structure further comprises an oxide film layer located between the first insulating layer and the second insulating layer.

16. The semiconductor device of claim 11, further comprising a second lower separation structure partially passing through the substrate in the vertical direction and located between the substrate and the bit line.

17. The semiconductor device of claim 16, wherein the second lower separation structure comprises:
a third vertical section located between the at least one semiconductor pattern and the bit line and extending in the vertical direction; and
a fourth vertical section located between the substrate and the bit line and extending in the vertical direction, and
wherein the third vertical section of the second lower separation structure has a third thickness, and
the fourth vertical section of the second lower separation structure has a fourth thickness that is less than the third thickness of the second lower separation structure.

18. The semiconductor device of claim 16, wherein an upper surface of the first lower separation structure is substantially coplanar with an upper surface of the second lower separation structure, and
a vertical level of the upper surface of the first lower separation structure and a vertical level of the upper surface of the second lower separation structure are each higher than or equal to a vertical level of a semiconductor pattern located lowermost among the plurality of semiconductor patterns.

19. A semiconductor device comprising:
a substrate;
a plurality of semiconductor patterns extending in a first horizontal direction, above the substrate, and spaced apart from one another in a second horizontal direction and a vertical direction, which intersect the first horizontal direction, the plurality of semiconductor patterns each comprising a first end and a second end;
a bit line connected to the first ends of the plurality of semiconductor patterns and extending in the vertical direction;
a plurality of word lines respectively surrounding the plurality of semiconductor patterns and extending in the second horizontal direction;
a plurality of cell capacitors respectively connected to the second ends of the plurality of semiconductor patterns;
a plate electrode connected to the plurality of cell capacitors and extending in the vertical direction; and
a lower separation structure partially passing through the substrate in the vertical direction and located at one or more positions among a position between the substrate and the bit line and a position between the substrate and the plate electrode,
wherein the lower separation structure comprises:
a first vertical section extending in the vertical direction, above the substrate, to cover at least one semiconductor pattern; and
a second vertical section extending in the vertical direction and partially passing through the substrate, and
wherein a thickness of the second vertical section of the lower separation structure is less than a thickness of the first vertical section of the lower separation structure.

20. The semiconductor device of claim 19, wherein the lower separation structure comprises a first insulating layer and a second insulating layer, which are sequentially disposed on the at least one semiconductor pattern, and
the first vertical section of the lower separation structure further comprises an oxide film layer located between the first insulating layer and the second insulating layer.
